(19) United States
(12) Patent Application Publication
(10) Pub. No.: US 2013/0105906 A1
(43) Pub. Date: May 2, 2013

(54) CMOS Device Having Dual Metal Gates and Method of Manufacturing the Same

(71) Applicants: Huaxiang Yin, Beijing (CN); Qiuxia Xu, Beijing (CN); Dapeng Chen, Beijing (CN)

(72) Inventors: Huaxiang Yin, Beijing (CN); Qiuxia Xu, Beijing (CN); Dapeng Chen, Beijing (CN)

(21) Appl. No.: 13/496,477

(22) PCT Filed: Nov. 28, 2011
(86) PCT No.: PCT/CN2011/001981

§ 371 Date: Mar. 15, 2012

(30) Foreign Application Priority Data
Oct. 26, 2011 (CN) 201110329080.1

(51) Int. Cl. H01L 27/092; H01L 21/8238

(52) U.S. Cl. 257/369; 438/585; 257/E27.062; 257/E21.637

(57) ABSTRACT

The present invention relates to a CMOS device having dual metal gates and a method of manufacturing the same. The device comprising: a semiconductor substrate; a first-type MOS device comprising a first gate stack and a second-type MOS device comprising a second gate stack and having an opposite conductivity type, the first-type MOS device and the second-type MOS device being formed on the substrate; wherein the first gate stack is comprised of a first gate insulating layer, a first work function regulating layer formed on the first gate insulating layer and applicable to the first-type MOS device, and a first filling metal layer surrounded by the first work function regulating layer from the bottom and sides, and the second gate stack is comprised of a second gate insulating layer, a second work function regulating layer formed on the second gate insulating layer and applicable to the second-type MOS device, and a second filling metal layer surrounded by the second function regulating layer from the bottom and sides.

### FIELD OF THE INVENTION

The present invention relates to the semiconductor field, particularly to a CMOS device having dual metal gates and a method of manufacturing the same.

### BACKGROUND OF THE INVENTION

Starting from the 45 nm CMOS integrated circuit technology, with continuous reduction in the device feature size, the equivalent oxide thickness (EOT) of a gate insulating dielectric layer must be reduced synchronously to suppress the short channel effect. However, the ultra-thin conventional oxide layer or oxynitride layer may result in severe gate leakage current, thus the poly-Si/SiON system is no longer applicable.

The interface of high-K materials and the internal polarization charges render difficulty in regulating the threshold of a device, the Fermi-level pinning effect produced by the combination of poly-Si and high-K is not suitable for regulating the threshold of a MOS device, so the gate electrode must use different metal materials to regulate the threshold of a device.

Metal electrodes of different work functions are needed for regulating the threshold of different MOS devices, for example, NMOS and PMOS devices. A single metal post-process regulating method may be adopted, but the regulating range is limited; the optimal process is to adopt gate electrodes of different metal materials, where conduction-band metal is needed by NMOS and valence-band metal is need by PMOS.

FIGS. 1-6 are cross-sectional views showing the structure of a device formed by the steps of integrating metal materials of different work functions into the PMOS and NMOS in the prior art of the CMOS integration technique.

An initial structure 10 as shown in FIG. 1 is provided by a conventional process. The initial structure 10 comprises a semiconductor substrate 100, in which a PMOS device and an NMOS device are formed. Wherein the PMOS device and NMOS device comprise their respective channels, gate stacks (comprising gate insulating layers 105A, 105B formed of oxide, oxynitride or high K dielectric materials; sacrificial gates 110A, 110B, respectively) formed above the channels, spacers around the gate stacks, source/drain extension regions under the spacers, sources/drains (S/D) formed on both sides of the spacers, and silicide contacts (not shown) formed on the sources/drains, and interlayer dielectric layers 115 formed on both sides of the spacers. Furthermore, the MOS devices may also be separated from each other by an isolation region, which may be, for example, a shallow trench isolation (STI) or field isolation region and may be formed of stressed materials or unstressed materials.

Sacrificial gates 110A and 110B are removed. In a preferred embodiment, since the above removing process may cause damage to the gate insulating layers below, gate insulating layers 105A and 105B are removed at the same time and then remanufactured. Then, an NMOS work function regulating layer 120 is deposited, as shown in FIG. 2. Wherein the method of removing sacrificial gates may include but not limited to an etching process. The deposition process may include but not limited to chemical vapor deposition (CVD), plasma assisted CVD, atomic layer deposition (ALD), evaporation, reaction sputtering, chemical solution deposition or other similar deposition processes, and the combination of any of the above processes. In addition, in this embodiment, the NMOS work function regulating layer is deposited first, but just as what is appreciated by those skilled in the art that the PMOS work function regulating layer may also be deposited first.

The NMOS work function regulating layer 120 on the PMOS device is remove by using a mask, then the PMOS work function regulating layer 125 is deposited, as shown in FIG. 3. Wherein the method of removing the NMOS work function regulating layer may include but not limited to an etching process. The deposition process may include but not limited to chemical vapor deposition (CVD), plasma assisted CVD, atomic layer deposition (ALD), evaporation, reaction sputtering, chemical solution deposition or other similar deposition processes, and the combination of any of the above processes. At this time, a PMOS work function regulating layer 125 exists on the NMOS work function regulating layer 120.

A filling metal layer 130 is deposited, as shown in FIG. 4. The deposition process may include but not limited to chemical vapor deposition (CVD), plasma assisted CVD, atomic layer deposition (ALD), evaporation, reaction sputtering, chemical solution deposition or other similar deposition processes, and the combination of any of the above processes.

Then, the filling metal layer 130, PMOS work function regulating layer 125 and NMOS work function regulating layer 120 are planarized to flush with the surface of the interlayer dielectric layer 115, as shown in FIG. 5.

Next, through other well-known steps, such as forming another interlayer dielectric layer 135 on the top surface of the sources/drains as well as the gate stacks for contact, a metal contact 140 is formed, thus the MOS device as shown in FIG. 6 is formed. In any of the cases, in order not to blur the essence of the present invention, those skilled in the art may get to know the details of these steps by referring to other publications and patents.

In the above conventional processes, the step of removing the NMOS work function regulating layer on the PMOS device may cause damage to the gate insulating layer 105A on the PMOS device. Although an etching stop layer may be added, this will increase the process complexity and reduce the ability of regulating the threshold of the device by the metal gate. Besides, in the NMOS device, the PMOS work function regulating layer 125 (which is deposited after the deposition of the NMOS work function regulating layer 120) is deposited on the NMOS work function regulating layer 120, thus this has negative effects on the threshold regulation on the NMOS device.

For the above reasons, there still exists a need for a new manufacturing method and device for CMOS device to overcome the above-stated damages and negative effects.

### SUMMARY OF THE INVENTION

The present invention provides in one aspect a CMOS device having dual metal gates, comprising: a semiconductor substrate; a first-type MOS device and a second-type MOS device having an opposite conductivity type formed on the semiconductor substrate, wherein the first-type MOS device and second-type MOS device respectively comprise: a first channel and a second channel; a first gate stack formed on the first channel and a second gate stack formed on the second channel; a first spacer surrounding the first gate stack and a second spacer surrounding the second stack; and a first source/drain formed on both sides of the first spacer and a second source/drain formed on both sides of the second spacer; wherein the first gate stack is comprised of a first gate insulating layer, a first work function regulating layer formed on the first gate insulating layer and applicable to the first-type MOS device, and a first filling metal layer surrounded by the first work function regulating layer from the bottom and sides, and the second gate stack is comprised of a second gate insulating layer, a second work function regulating layer formed on the second gate insulating layer and applicable to the second-type MOS device, and a second filling metal layer surrounded by the second function regulating layer from the bottom and sides.

The present invention provides in another aspect a method for manufacturing a CMOS device having dual metal gates, comprising the steps of:

providing an initial structure comprising a semiconductor substrate, a first-type MOS device and a second-type MOS device having an opposite conductivity type formed on the semiconductor substrate, wherein the first-type MOS device and second-type MOS device respectively comprise a first channel and a second channel, a first gate stack formed on the first channel and a second gate stack formed on the second channel, a first spacer surrounding the first gate stack and a second spacer surrounding the second stack as well as a first source/drain formed on both sides of the first spacer and a second source/drain formed on both sides of the second spacer, wherein the first gate stack is comprised of a first gate insulating layer and a first sacrificial gate formed on the first gate insulating layer, and the second gate stack is comprised of a second gate insulating layer and a second sacrificial gate formed on the second gate insulating layer; removing the first sacrificial gate and the second sacrificial gate; masking the second-type MOS device by a mask; depositing the first work function regulating layer applicable to the first-type MOS device; removing the mask, thus the first work function regulating layer on the mask is stripped off; masking the first-type MOS device by another mask; depositing the second work function regulating layer applicable to the second-type MOS device; removing the another mask, thus the second work function regulating layer on the another mask is stripped off; and depositing a filling metal layer and performing planarization.

In accordance with the method and device of the present invention, no steps of removing the work function regulating layer of an opposite type from the gate insulating layer in the conventional process exist, thus no damages will be caused to the gate insulating layer. Furthermore, no PMOS/NMOS work function regulating layer exists on the NMOS/PMOS work function regulating layer, thus no negative effect will be produced to the threshold regulation of the NMOS/PMOS device.

### BRIEF DESCRIPTION OF THE DRAWINGS

To understand the present invention well and to show how it is effected, the accompanying drawings will now be referenced through the embodiments, wherein:

FIGS. 1-6 are cross-sectional views showing the structure of a device formed by the steps of integrating metal materials of different work functions into the PMOS and NMOS in accordance with the prior art; and

FIGS. 7-15 are cross-sectional views showing the structure of a device formed by the steps of integrating metal materials of different work functions into the PMOS and NMOS in accordance with the present invention.

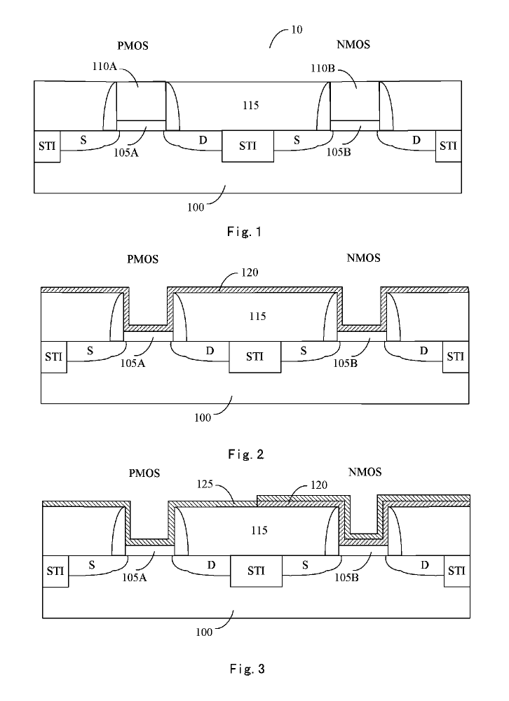

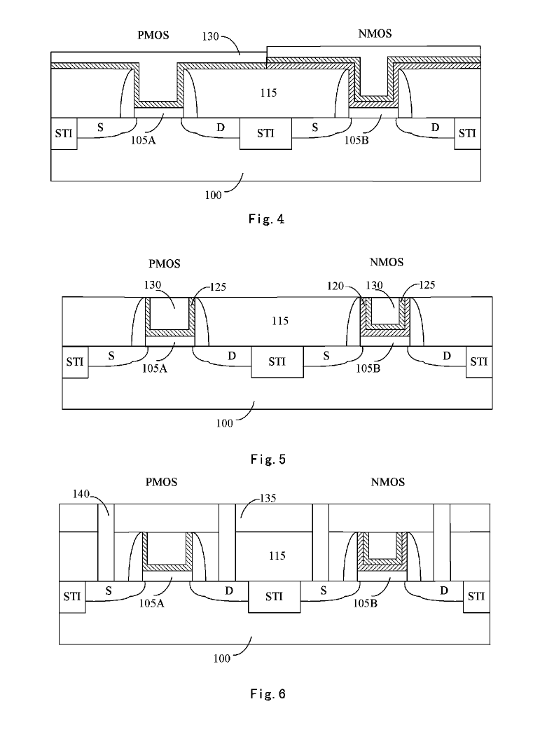

### DETAILED DESCRIPTION OF THE EMBODIMENTS

One or more aspects of the embodiment of the present invention will described with reference to the accompanying drawings below, where like elements will be generally indicated by like reference signs throughout the drawings. In the following descriptions, many specific details are elaborated for the purpose of explanation so as to facilitate thorough understanding of one or more aspects of the embodiment of the present invention. However, it may be apparent to those skilled in the art that they may use few of these specific details to implement one or more aspects of the embodiment of the present invention.

In addition, although the specific features or aspects of an embodiment are merely disclosed by one of the implementions, such specific features or aspects may be incorporated with one or more other features or aspects of other implementions that may be advantageous to and desired by any given or specific applications.

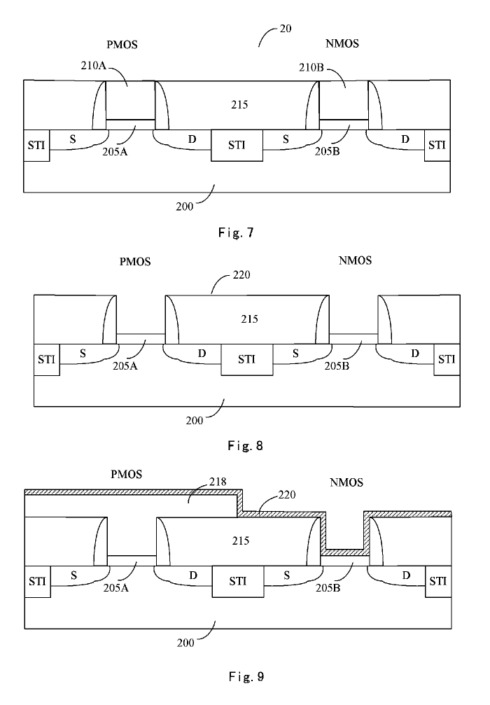

FIGS. 7-15 are cross-sectional views showing the structure of a device formed by the steps of integrating metal materials of different work functions into the PMOS and NMOS in accordance with the present invention.

An initial structure 20 as shown in FIG. 7 is provided. The initial structure 20 comprises a semiconductor substrate 200, in which a PMOS device and an NMOS device are formed. Wherein the PMOS device and NMOS device comprise their respective channels, gate stacks (comprising gate insulating layers 205A, 205B formed of oxide, oxynitride or high K dielectric materials; sacrificial gates 210A, 210B, respectively) formed above the channels, spacers surrounding the gate stacks, source/drain extension regions under the spacers, sources/drains (S/D) formed on both sides of the spacers, and silicide contacts (not shown) formed on the sources/drains, and interlayer dielectric layers 215 formed on both sides of the spacers. Furthermore, the MOS devices may be separated from each other by an isolation region, which may be, for example, a shallow trench isolation (STI) or field isolation region and may be formed of stressed materials or unstressed materials.

Optionally, a conventional stressed structure (not shown in the drawings) may be embedded into the S/D regions on both sides of the gate stack. As for the NMOS device, for example, an SiC (e-SiC) structure or a structure that can provide a tensile stress to the channel formed by any future techniques is embedded into the S/D regions. As for the PMOS device, for example, an SiGe (e-SiGe) structure or a structure that can provide a compressive stress to the channel formed by any future techniques is embedded into the S/D regions.

Optionally, a stress liner (not shown) may also be formed on the top of the intermediate structure of the device prior to the formation of the interlayer dielectric layer 215 and may be planarized with the interlayer dielectric layer 215 upon the formation of the layer 215 to expose the surface of the sacrificial gates 210A and 210B. Depending on the type of the MOS device, the liner may apply a corresponding stress to the channel regions under the gate stacks. The stress liner may either be a nitride liner or an oxide liner. However, it may be appreciated by those skilled in the art that the stress liner is not limited to the nitride liner or the oxide liner, other stress liner materials may also be used. The method for forming the stress liner may include but not limit to the plasma enhanced chemical vapor deposition (PECVD) process.

The materials for forming the gate insulating layers 205A and 205B may include but not limited to HfO2, HfSiOx, HfSiON, HfAlOx, HfTaOx, HfLaOx, HfAlSiOx, and HfLaSiOx etc., rare-earth based high K dielectric materials ZrO2, La2O3, LaAlO3, TiO2, Y2O3 etc., and SiO2, SiON, Si3N4, Al2O3 etc. The materials for the gate insulating layers 205A and 205B may be the same or not the same. The gate insulating layers may be formed by a deposition process such as chemical vapor deposition (CVD), plasma assisted CVD, atomic layer deposition (ALD), evaporation, reaction sputtering, chemical solution deposition or other similar deposition processes and the combination of any of the above processes.

Sacrificial gates 210A and 210B may be formed of, e.g., polysilicon or other materials commonly known in the art, and their materials may be the same or not the same.

The sacrificial gates 210A and 210B are removed to form two openings, as shown in FIG. 8. The method for removing the sacrificial gates may include but not limited to an etching process, including wet etching or dry etching such as reactive ion etching (RIE).

Since the above etching process may cause damage to the gate insulating layers 205A and 205B below, preferably, gate insulating layers 205A and 205B are removed at the same time and then remanufactured. The materials for the new gate insulating layers 205A and 205B may include but not limited to HfO2, HfSiOx, HfSiON, HfAlOx, HfTaOx, HfLaOx, HfAlSiOx, and HfLaSiOx etc., rare-earth based high K dielectric materials ZrO2, La2O3, LaAlO3, TiO2, Y2O3 etc., and SiO2, SiON, Si3N4, Al2O3 etc. The materials for the gate insulating layers 205A and 205B may be the same or not the same.

A mask layer 218 is formed on the PMOS device. The formation of the mask layer 218 is achieved by spin coating a photoresist (PR) or other organics on the above structure, patterning it to remove the PR or other organics on the NMOS device, thereby leaving the PR or other organics on the PMOS device only.

Next, an NMOS work function regulating layer is formed on the above structure such that the work function is ≦4.5 eV, as shown in FIG. 9. The NMOS work function regulating layer with the work function is ≦4.5 eV may be, for example, the conduction-band metal formed by a deposition process such as low temperature CVD, low temperature PECVD, low temperature ALD, sputtering, or other similar processes, for example, one of Ti, Ta, TiN, TaN, Si, TiSi, TaSi, Mo, MoSi, TiSiN, TaSiN and/or the combinations thereof and/or the multi-layer structures thereof.

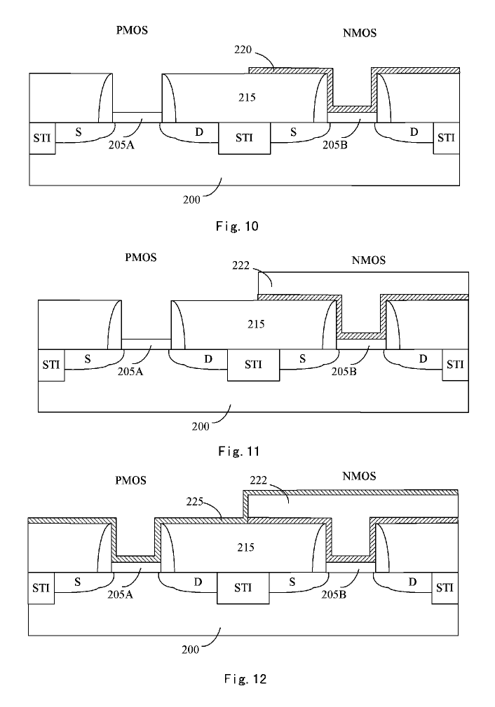

The mask layer 218 on the PMOS device is removed, and the NMOS work function regulating layer 220 thereon is removed together, as shown in FIG. 10. For example, the PR or other organics on the PMOS device are stripped off such that the NMOS work function regulating layer 220 on the PR or other organics can be stripped off together, thereby leaving the NMOS work function regulating layer 220 on the NMOS device.

Another mask layer 222, as shown in FIG. 11, is formed on the NMOS device. The formation of the another mask layer 222 is achieved by spin coating a photoresist (PR) or other organics on the above structure as shown in FIG. 10, patterning it to remove the PR or other organics on the PMOS device, thereby leaving the PR or other organics on the NMOS device only.

Then, a PMOS work function regulating layer 225 is formed on the above structure such that the work function is ≧4.5 eV, as shown in FIG. 12. The PMOS work function regulating layer with the work function is ≧4.5 eV may be, for example, the valence-band metal formed by a deposition process such as low temperature CVD, low temperature PECVD, low temperature ALD, sputtering, or other similar processes, for example, one of Ni, Pt, Ir, Ru, Ti enriched TiN, Ta enriched TaN, Mo, MoN and/or the combinations thereof and/or the multi-layer structures thereof.

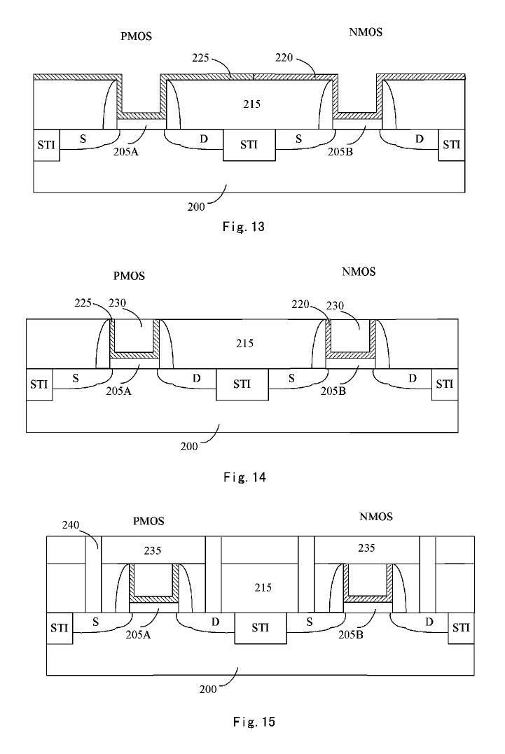

The mask layer 222 on the NMOS device is removed, and the PMOS work function regulating layer 225 thereon is removed together, as shown in FIG. 13. For example, the PR or other organics on the NMOS device are stripped off such that the PMOS work function regulating layer 225 on the PR or other organics can be stripped off together, thereby leaving the PMOS work function regulating layer 225 on the PMOS device.

A filling metal layer 230 is deposited. The material for the filling metal layer 230 may be, for example, one of Al, W and Cu and/or the combinations thereof. The deposition process may include but not limited to chemical vapor deposition (CVD), plasma assisted CVD, atomic layer deposition (ALD), evaporation, reaction sputtering, chemical solution deposition or other similar deposition processes and the combination of any of the above processes.

The filling metal layer 230, PMOS work function regulating layer 225 and NMOS work function regulating layer 220 are planarized to expose the surface of the interlayer dielectric layer 215, as shown in FIG. 14.

Preferably, a blocking layer (not shown in the drawings) may be formed between the work function regulating layers 220, 225 and the filling metal layer 230. The material for the blocking layer may be, for example, one of TiN, TaN, WN or the combinations thereof. Furthermore, the material for the blocking layer and that for the filling metal layer may be the same or not the same. The blocking layer may suppress the mutual diffusion of different elements in the work function regulating layer and the filling metal layer, thereby improving the work function stability of the surface metal materials, and improving the adhesivity of the filling metal layer and the gate structure in the mean time.

Next, through other well-known steps, such as forming another interlayer dielectric layer 235 on the top surface of the sources/drains as well as the gate stacks for contact, and forming metal contacts 240, thus the MOS device as shown in FIG. 15 is formed. In any of the cases, in order not to blur the essence of the present invention, those skilled in the art may get to know the details of these steps by referring to other publications or patents.

In accordance with the method and device of the present invention, no steps of removing the work function regulating layer of an opposite type from the gate insulating layer in the conventional process exist, thus no damages will be caused to the gate insulating layer. Furthermore, no PMOS/NMOS work function regulating layer exists on the NMOS/PMOS work function regulating layer, thus no negative effect will be produced to the threshold regulation of the NMOS/PMOS device.

The integration method for independently regulating the work function of integrated dual metal gates of the present invention may be applied to a device which takes the strained Si, SiGe, Ge, III-V, grapheme, II-VI as the material for the channel region.

The integration method for independently regulating the work function of dual metal gates of the present invention may be applied to device structures such as Fin field effect transistors (FinFET), Tri-Gate transistors, and nano wires.

The above disclosed are the preferred embodiments of the present invention, which do not intend to limit the present invention. For example, although the embodiments describe the step of depositing the NMOS work function regulating layer first, it will be apparent to those skilled in the art that the PMOS work function regulating layer may be deposited first. Then, some process sequences will be modified. Therefore, various modifications and variations may be made to the present invention without departing from the principle of the technical method and the scope of the attached Claims of the present invention.

What is claimed is:

1. A CMOS device having dual metal gates, comprising:
a semiconductor substrate;
a first-type MOS device comprising a first gate stack and a second-type MOS device comprising a second gate stack and having an opposite conductivity type, the first-type MOS device and the second-type MOS device being formed on the substrate;
wherein the first gate stack is comprised of a first gate insulating layer, a first work function regulating layer formed on the first gate insulating layer and applicable to the first-type MOS device, and a first filling metal layer surrounded by the first work function regulating layer from the bottom and sides, and the second gate stack is comprised of a second gate insulating layer, a second work function regulating layer formed on the second gate insulating layer and applicable to the second-type MOS device, and a second filling metal layer surrounded by the second function regulating layer from the bottom and sides.

2. The CMOS device according to claim 1, wherein the first gate stack further comprises a first blocking layer formed between the first work function regulating layer and the first filling metal layer, and the second gate stack further comprises a second blocking layer formed between the second work function regulating layer and the second filling metal layer.

3. The CMOS device according to claim 1, wherein the first-type device is an NMOS, and the second-type device is a PMOS.

4. The CMOS device according to claim 3, wherein the first work function regulating layer is formed of conduction-band metal, and the second work function regulating layer is formed of valence-band metal.

5. The CMOS device according to claim 4, wherein the work function of the conduction-band metal is ≦4.5 eV, and the work function of the valence-band metal is ≧4.5eV.

6. The CMOS device according to claim 5, wherein the conduction-band metal is one of Ti, Ta, TiN, TaN, Si, TiSi, TaSi, Mo, MoSi, TiSiN, TaSiN and/or the combinations thereof and/or the multi-layer structures thereof, and the valence-band metal is one of Ni, Pt, Ir, Ru, Ti enriched TiN, Ta enriched TaN, Mo, MoN and/or the combinations thereof and/or the multi-layer structures thereof.

7. The CMOS device according to claim 1, wherein the material for the filling metal layer is one of Al, W, Cu or the combinations thereof.

8. The CMOS device according to claim 2, wherein the material for the blocking layer is one of TiN, TaN, WN or the combinations thereof.

9. A method for manufacturing a CMOS device having dual metal gates, comprising the steps of:
providing a semiconductor substrate,
forming a first-type MOS device comprising a first gate stack and a second-type MOS device comprising a second gate stack and having an opposite conductivity type on the semiconductor substrate, wherein the first gate stack is comprised of a first gate insulating layer and a first sacrificial gate formed on the first gate insulating layer, and the second gate stack is comprised of a second gate insulating layer and a second sacrificial gate formed on the second gate insulating layer;
removing the first sacrificial gate and the second sacrificial gate;
masking the second-type MOS device by a mask;
depositing the first work function regulating layer applicable to the first-type MOS device;
removing the mask, thus the first work function regulating layer on the mask is stripped off;
masking the first-type MOS device by another mask;
depositing the second work function regulating layer applicable to the second-type MOS device;
removing the another mask, thus the second work function regulating layer on the another mask is stripped off; and
depositing a filling metal layer and performing planarization.

10. The method according to claim 9, further comprising forming a first blocking layer between the first work function regulating layer and the first filling metal layer, and forming a second blocking layer between the second work function regulating layer and the second filling metal layer.

11. The method according to claim 9, wherein the first-type device is an NMOS, and the second-type device is a PMOS.

12. The method according to claim 11, wherein the first work function regulating layer is formed of conduction-band metal, and the second work function regulating layer is formed of valence-band metal.

13. The method according to claim 12, wherein the conduction-band metal and the valence-band metal are formed by low temperature CVD, low temperature PECVD, or low temperature ALD such that the work function of the conduction-band metal is ≦4.5 eV, and the work function of the valence-band metal is ≧4.5 eV.

14. The method according to claim 13, wherein the conduction-band metal is one of Ti, Ta, TiN, TaN, Si, TiSi, TaSi, Mo, MoSi, TiSiN, TaSiN and/or the combinations thereof and/or the multi-layer structures thereof, and the valence-band metal is one of Ni, Pt, Ir, Ru, Ti enriched TiN, Ta enriched TaN, Mo, MoN and/or the combinations thereof and/or the multi-layer structures thereof.

15. The method according to claim 9, wherein the material for the filling metal layer is one of Al, W, Cu or the combinations thereof.

16. The method according to claim 10, wherein the material for the blocking layer is one of TiN, TaN, WN or the combinations thereof.
